(19) United States
(12) Patent Application Publication
(10) Pub. No.: US 2007/0013380 A1
(43) Pub. Date: Jan. 18, 2007

(54) Circuit breaker with integrated ammeter

(76) Inventor: Kenny Word, Avinger, TX (US)

Correspondence Address: Ronald B. Sefrna, P.O. Box 567, Tyler, TX, 75710, US

(21) Appl. No.: 11/486,968

(22) Filed: Jul. 13, 2006

Related U.S. Application Data
(60) Provisional application No. 60/698,844, filed on Jul. 13, 2005.

(51) Int. Cl. G01R 31/327; G01R 31/02

(52) U.S. Cl. 324/424

(57) ABSTRACT

An integrated circuit breaker and ammeter device includes a generally conventional electrical circuit breaker with an enclosing case and a primary current carrying conductor running through the case, and an ammeter circuit mounted with the case and operatively connected to the primary conductor so as to read and display the value of the current flowing through the primary conductor of the circuit breaker. In the preferred embodiment the primary conductor functions as the primary winding of a transformer and the ammeter circuit is directly connected to the secondary transformer winding. The ammeter circuit preferably further includes a display panel mounted on the case in a readily visible location.

### RELATED APPLICATION DATA

This application claims the benefit of U.S. Provisional Patent Application Ser. No. 60/698,844, filed Jul. 13, 2005, titled “Circuit Breaker With Integrated Ammeter”.

### FIELD OF THE INVENTION

The present invention generally relates to electrical circuit breakers, and in its preferred embodiments more specifically relates to circuit breakers with an integrated ammeter for showing current flow through the circuit breaker and the electrical circuit protected by the breaker.

### BACKGROUND

Electrical systems in buildings, industrial facilities, and the like are almost universally divided into a number of different circuits, each typically including or providing power to a number of receptacles, lights, and other devices that draw electrical power. Each circuit is designed to safely carry or conduct electricity to support a specified power load on the circuit, or on the electrical wiring making up the circuit. As a safety measure, each circuit is, in modem installations, protected by a circuit breaker device to interrupt the flow of electricity through the circuit if the power load on the circuit, or the current flow through the circuit, exceeds the acceptable safe limit. A circuit breaker is essentially a switch device that remains closed when the current flow through the breaker is within the design limit, and that will automatically open when the current flow exceeds that which has been determined to be safe for the circuit.

In a typical installation, electrical power to, e.g., a building, is fed to a power panel or box within which the wiring for each circuit within the building terminates, and the circuit breakers for all electrical circuits in the building are located in the panel. When a circuit breaker opens, or trips, the breaker can be reset by means of a switch located on the breaker itself. It is not uncommon for the load on a circuit to occasionally exceed the capacity of the breaker and cause the breaker to open, even though the load on the circuit is normally within safe limits. Often the breaker can be reset and the circuit returned to service with no further problems. Sometimes, however, simply resetting the breaker does not resolve the problem and the breaker continues to open.

In that situation there are several potential causes for the problem, including excessive load on the circuit, a problem with the wiring making up the circuit, a problem with a device wired into the circuit, or a problem with the breaker itself. It is important to determine the cause of the problem so that it can be properly corrected and the circuit returned to service without compromising the safety of the electrical system, but making that determination can be a time consuming process, even for a skilled electrician. The current flow through the circuit is a significant factor in evaluating the circuit and diagnosing the problem, and an electrician will typically use an ammeter to measure the current flow. However, connecting an ammeter, especially with the breaker in place, is not always an easy task.

### SUMMARY OF THE INVENTION

The present invention addresses and resolves the difficulties and problems associated with monitoring current flow through a circuit that are not effectively addressed by circuit breaker designs known in the prior art and by prior art techniques based upon the use of conventional circuit breakers. The present invention provides a circuit breaker with an integrated ammeter with a display to provide a continuous reading of current flow through a circuit.

In the preferred embodiment the conductor carrying electrical current through the circuit breaker is routed through a transformer in which the circuit breaker conductor functions as the primary winding, and secondary winding carries induced current through an ammeter circuit. A display panel mounted on the front face of the circuit breaker displays the value of the current flowing through the primary circuit breaker conductor.

The structure and features of the circuit breaker of the invention will be described below with reference to the accompanying drawing figures.

### BRIEF DESCRIPTION OF THE DRAWINGS

FIG. 1 is a side elevation view of a conventional, prior art, circuit breaker, with the side of the case removed to illustrate the internal components.

FIG. 2 is a side elevation view of a circuit breaker of the invention, with the side of the case removed, schematically showing the components and wiring for the integrated ammeter.

FIG. 3 is a front elevation view of a circuit breaker of the invention, showing the ammeter display screen.

FIG. 4 is a schematic electrical circuit diagram of the circuit breaker of the invention, with power supply to the circuit breaker and output from the circuit breaker to the protected circuit.

### DESCRIPTION OF THE INVENTION

The circuit breaker of the invention utilizes conventional circuit breaker design, and generally comprises an improvement of the conventional circuit breaker. The utilization of a conventional circuit breaker design to perform the circuit interruption or breaking function of the device is intended to minimize the cost of production of the circuit breaker of the invention, since it facilitates and use of many pre-existing components and existing production facilities with limited modification.

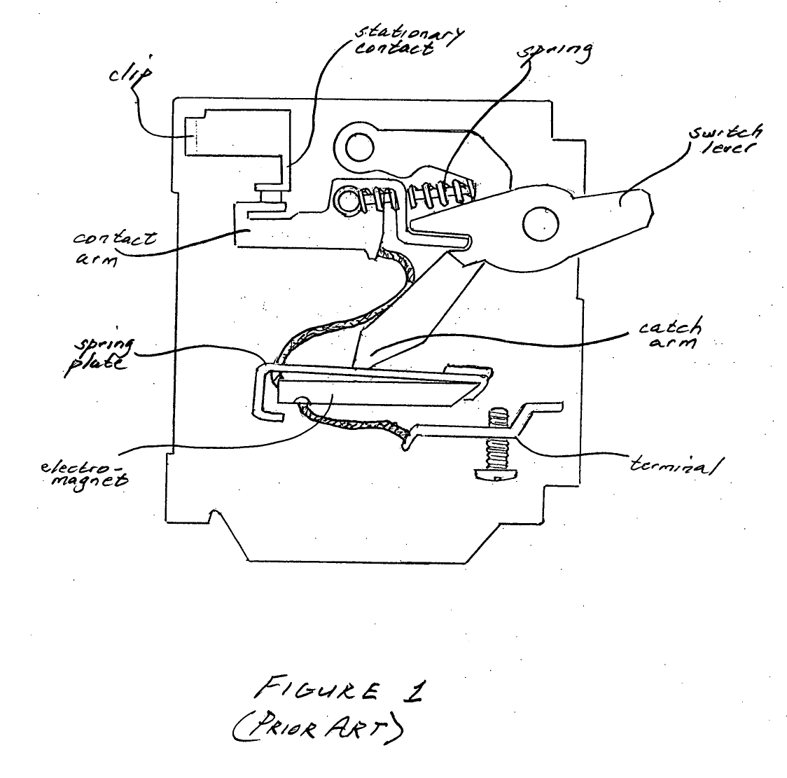

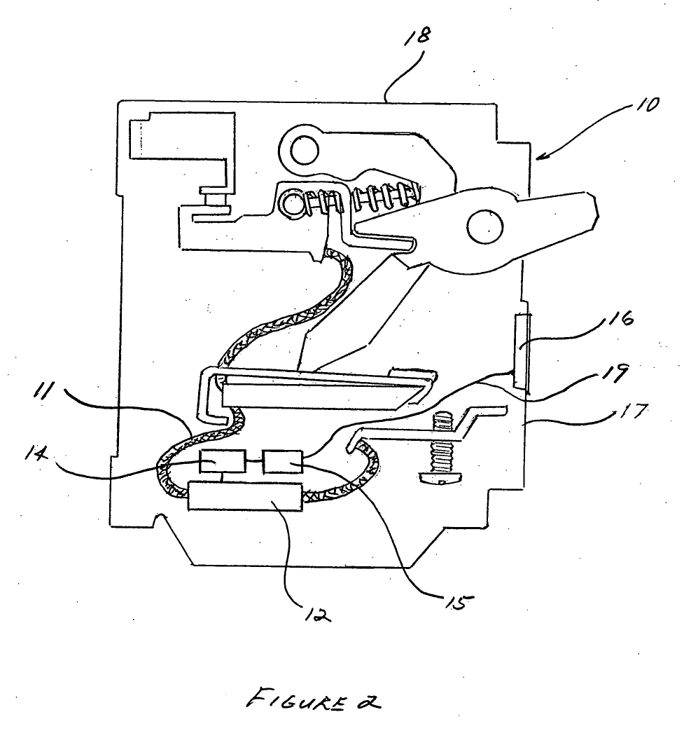

A conventional circuit breaker of the electromagnet type is illustrated in FIG. 1. In a typical electrical circuit the “common ” wire of the circuit wiring is connected to a common bus bar in the electrical panel and the “ground ” wire is connected to a ground bar. Only the “hot ” wire for the circuit is connected to the circuit breaker. The circuit breaker is then connected to the hot bus in the electrical panel, so that the current to the circuit protected by the circuit breaker passes through the internal circuit breaker mechanism.

A typical circuit breaker as illustrated includes a terminal (or choice of terminals) for connection of the hot wire of the protected circuit, a bus clip and stationary contact for connection to the panel bus, and a switchable circuit through the circuit breaker connecting the stationary contact with the hot wire terminal. In the illustrated circuit breaker the electrical current flows through an electromagnet in the interior of the breaker and through a contact arm that is movable between a closed position in contact with the stationary contact and an open position separated from the stationary contact. The contact arm is spring biased toward the open position, and is connected to a breaker switch lever that allows the breaker to be manually set to an open position or to a closed position. The contact arm is held in the closed position by a pivoting catch arm, one end of which engages the contact arm and the other end of which engages a notch in a spring plate disposed adjacent to the electromagnet.

When current is flowing through the circuit breaker circuitry the electromagnet is energized, and the magnetic force generated by the magnet is directly proportional to the magnitude of the current flowing through it. The magnetic force is imposed upon the spring plate, tending to pull the plate toward the magnet against the spring bias of the plate which resists the magnetic force. When the current flowing through the electromagnet reaches a high enough level the magnetic force exerted by the magnet overcomes the spring bias of the spring plate, moving the spring plate toward the magnet sufficiently to release the catch arm from the notch in the spring plate. When the catch arm is released the moving contact arm is freed from the catch arm restraint, and the spring bias acting upon the moving contact arm causes it to rotate and separate from the stationary contact, breaking the electrical circuit through the circuit breaker. The manual switch lever moves to a “tripped ” position, providing a visual indication that the circuit breaker has tripped to open the protected circuit. In some breaker designs the electromagnet is not used and the current flows directly through a spring plate, or catch retaining plate, which is formed of a bimetal material that will deform as current flow through the plate heats the plate, eventually releasing the catch arm.

When a circuit breaker has tripped it can be reset by manually moving the external switch lever to the fully open position and then back to the closed position. If the problem in the protected circuit that caused the circuit breaker to trip was a temporary event or has been identified and resolved, the breaker will remain closed to return the protected circuit to service. Repeated tripping of a circuit breaker indicates a problem in the circuit, which can be, as noted above, difficult to identify and resolve. Although circuit breakers are generally very reliable, they are subject to failure or improper operation. Therefore, the problem causing a breaker to trip may be in the circuit wiring, in a device connected to the circuit, or in the breaker itself. A failed circuit breaker may open prematurely, at a current flow that is within the safe range for the circuit, or may fail to open when the current reaches unsafe levels. Regardless of the nature of the problem in the circuit, it should be promptly diagnosed and corrected.

An ammeter is frequently used as a diagnostic tool for resolving a problem in a circuit, but in common practice an actual measurement of the current flowing through a circuit is made only after a failure has occurred or the existence of a problem has otherwise become known. It would be desirable and advantageous to have the ability to monitor current flow in a circuit at other times, but that ability has not, as a practical matter been previously available.

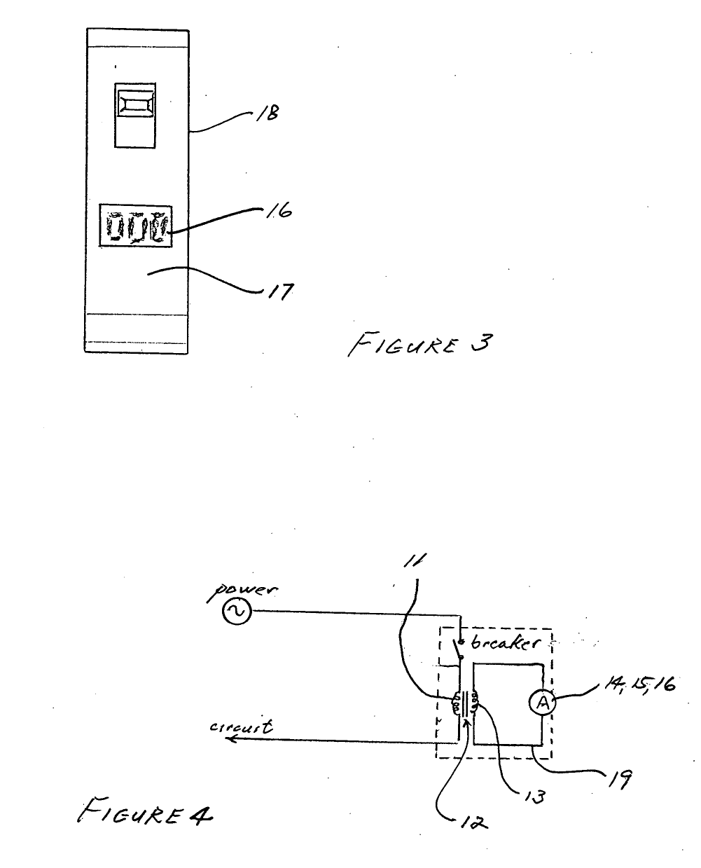

The present invention includes a generally conventional circuit breaker assembly 10 with the addition of an integral ammeter integrated into the circuit breaker wiring, to provide a continuous display of the current flowing through the primary conductor 11 of the circuit breaker, and thus through the external circuit in which the breaker is installed. In the preferred embodiment of the invention the ammeter circuitry is not directly connected to the current carrying primary conductor 11 of the circuit breaker 10, but is indirectly connected through a transformer 12, through which the power wiring is routed. In the transformer 12 the circuit breaker conductor 11 serves as the primary winding, and the flow of current through conductor 11 induces a current flow in secondary ammeter winding 13. Winding 13 is included in a wiring loop that includes an ammeter circuit 14, a display generator circuit 15, and a liquid crystal display (LCD) panel 16 disposed in the front face 17 of the case 18 of the circuit breaker 10 of the invention, connected by secondary electrical wiring 19. The display panel can be oriented in the face of the breaker so that it can be easily read when the breaker is in place in an electrical panel. In most electrical panels the circuit breakers are oriented horizontally but are oriented in opposing mirrored relation on either side of the vertical centerline of the panel, so it is contemplated that a standardized orientation will be preferred, as indicated in FIG. 3.

The ammeter and display generator are preferably integrated circuits on either separate chips or boards, or, if desired, combined on a single chip or board. Transformer 12 is not directly connected to the power circuit and imposes no load on that circuit. In the preferred embodiment the ammeter utilizes an inexpensive average-detecting rectifier circuit, such as those utilized in inexpensive clamp type hand held ammeters, that can be easily calibrated to provide an accurate reading of current flow through the primary conductor 11 of the circuit breaker, based on the 60 Hz frequency of the current flowing through conductor 11. The load from the display generator circuit and the LCD display panel is steady and very low, and is provided by the current in the ammeter wiring loop. The ammeter circuitry has no moving parts, and the components for the meter circuit can be produced inexpensively. In the preferred embodiment the LCD panel is a simple display without backlighting. Such a display can be easily read in ambient light or, in dim light, with the aid of a flashlight or other artificial light source. However, a backlit LCD display could readily be used if desired. Backlighting the display would facilitate reading regardless of the ambient light level, but would increase the cost of the display panel component.

In an alternative approach a more conventional analog-type ammeter circuit could be used, but such circuitry, which would require a high resistance shunt in the ammeter leg as well as a transformer to provide power to the display circuitry, is more cumbersome, more difficult to fit within existing circuit breaker casings without more extensive modification, and more expensive to construct.

In another alternative embodiment a light emitting diode (LED) display panel could be used instead of an LCD display. Although the power requirement for an LED display is higher than for an LCD display, the difference in power requirements is not significant. However, the use of an LED display would increase the cost of the ammeter system and thus the cost of the circuit breaker, and the increased brightness of an LED display is not necessary for the functionality of the meter display in most installations.

In a variation, the LCD panel, or LED panel if used, may be mounted on the face of the circuit breaker so that the display panel can be rotated, allowing the orientation of the display panel to be adjusted, depending on the orientation in which a circuit breaker is installed in an electrical panel, to facilitate reading the display.

Circuit breakers with an integral ammeter in accordance with the invention provide a continuous display of the current flowing through the circuit in which each circuit breaker is installed, and eliminate the need to remove the face plate of the electrical panel to gain access to the wiring behind it. The inclusion of an integral, continuously reading ammeter is not only a great advantage in diagnosing a problem with a circuit, but also allows the load on a circuit to be evaluated easily. Such an evaluation can be of significant benefit in determining, for example, whether additional load, such as an additional appliance, can be safely and appropriately added to a circuit. Other advantages and benefits associated with the circuit breaker of the invention will be perceived and appreciated by electricians and others knowledgeable of the field.

The foregoing description is intended to be illustrative and not limiting. The invention is susceptible to additional embodiments and variations within the scope of the invention, as recited in the following claims.

1. An electrical circuit breaker and integrated ammeter device, comprising,
a conventional circuit breaker assembly having a case and a primary conductor in said case for carrying electrical current through the circuit breaker;
an electrical transformer having a primary winding and a secondary winding, disposed in said case, with said primary conductor being said primary winding of said transformer; and
an ammeter circuit electrically connected to said secondary winding of said transformer and disposed in said case, for determining and displaying the amperage of the electrical current flowing through said primary conductor.

2. The electrical circuit breaker and integrated ammeter device of claim 1, wherein said ammeter circuit includes an average-detecting rectifier circuit.

3. The electrical circuit breaker and integrated ammeter device of claim 1, wherein said ammeter circuit includes a display generator circuit to receive an output signal therefrom and generate a display signal.

4. The electrical circuit breaker and integrated ammeter device of claim 3, wherein said ammeter circuit further includes a display panel electrically connected to said display generator to receive said display signal therefrom and produce a readable display.

5. The electrical circuit breaker and integrated ammeter device of claim 4, wherein said display panel is mounted in said front face of said case.

6. The electrical circuit breaker and integrated ammeter device of claim 4, wherein said display panel is a liquid crystal display.

7. The electrical circuit breaker and integrated ammeter device of claim 4, wherein said display panel includes light emitting diodes for producing said readable display.

8. An electrical circuit breaker and integrated ammeter device, comprising,
a conventional circuit breaker assembly having a case and a primary conductor in said case for carrying electrical current through the circuit breaker;
an electrical transformer having a primary winding and a secondary winding, disposed in said case, with said primary conductor being said primary winding of said transformer;
an ammeter circuit electrically connected to said secondary winding of said transformer and disposed in said case, said ammeter circuit calibrated to provide an output signal indicative of the current flowing through said primary conductor;
a display generator circuit disposed in said case and electrically connected to said ammeter to receive said output signal therefrom and generate a display signal; and
a display panel electrically connected to said display generator to receive said display signal therefrom and produce a readable display, said display panel mounted on said case.

9. The electrical circuit breaker and integrated ammeter device of claim 8, wherein said display panel is a liquid crystal display.

10. The electrical circuit breaker and integrated ammeter device of claim 8, wherein said display panel includes light emitting diodes for producing said readable display.

11. The electrical circuit breaker and integrated ammeter device of claim 8, wherein said case includes a front face, and wherein said display panel is mounted in said front face.

12. The electrical circuit breaker and integrated ammeter device of claim 8, wherein said ammeter circuit is an average-detecting rectifier circuit.

13. In an electrical circuit breaker having a case and primary conductor disposed in the case for carrying electrical current through the circuit breaker, the improvement comprising,
an ammeter circuit disposed in the case of the circuit breaker and operatively coupled to the primary conductor of the circuit breaker for reading and displaying the current flowing through the primary conductor of the circuit breaker.

14. The improvement of claim 13, wherein said ammeter circuit includes a display panel for displaying the value of the current flowing through the primary conductor.

15. The improvement of claim 14, wherein the case of the circuit breaker includes a front face, and wherein said display panel is mounted in said front face.

16. The improvement of claim 14, wherein said display panel is a liquid crystal display.

17. The improvement of claim 13, further comprising an electrical transformer with a primary winding and a secondary winding, wherein the primary conductor of the circuit breaker is said primary winding of said transformer, and wherein said ammeter circuit is directly connected to said secondary winding of said transformer.
